(19) United States
(12) Patent Application Publication
(10) Pub. No.: US 2025/0393261 A1
(43) Pub. Date: Dec. 25, 2025

(54) SYSTEM FOR QUANTUM INFORMATION PROCESSING

(71) Applicants: The University of Warwick, Coventry, West Midlands (GB); The Chancellor, Masters and Scholars of the University of Oxford, Oxfordshire (GB)

(72) Inventors: Gavin MORLEY, Coventry, West Midlands (GB); Jason SMITH, Oxfordshire (GB)

(73) Assignees: The University of Warwick, Coventry, West Midlands (GB); The Chancellor, Masters and Scholars of the University of Oxford, Oxfordshire (GB)

(21) Appl. No.: 18/880,443

(22) PCT Filed: Jul. 5, 2023
(86) PCT No.: PCT/GB2023/051777

§ 371 Date: Dec. 31, 2024

(30) Foreign Application Priority Data
Jul. 6, 2022 (GB) 2209944.4

(51) Int. Cl. H10D 48/00; B82Y 10/00; G06N 10/40; H10D 62/53; H10D 62/83; H10D 62/832

(52) U.S. Cl. CPC H10D 48/383; B82Y 10/00; G06N 10/40; H10D 48/385; H10D 62/53; H10D 62/8303; H10D 62/8325

(57) ABSTRACT

A system for quantum information processing (1) is described which includes a body of material (2) having first and second opposite faces (3, 4) and at least one two-dimensional array (7) of defects (5_{i,k}, 5_{i+1,k}, 5_{i,k+1} . . . 5_{n,m}) embedded in the body of material at a depth (d₁) of between 0.2 μm and 6 μm from the first face.

### FIELD OF THE INVENTION

The present invention relates to a system for processing quantum information, including storing quantum information. The present invention also relates to apparatus including the system, a method of fabricating the system, and a method of operating the system.

### BACKGROUND

If a future quantum computer could be built with more qubits and high enough gate fidelity then it should be able to outperform classical computers for certain useful tasks such as simulating quantum systems and factorizing large numbers. There are proposals to build quantum computers using electron and nuclear spins in semiconductors/insulators as qubits.

One set of proposals focuses on spin qubits in diamond. Several colour centres in diamond are considered for the role of the spin qubit, and nitrogen-vacancy centres are the most well studied so far. Nitrogen-vacancy centres have long electron and nuclear spin coherence times, and high-fidelity quantum control has been demonstrated for this system using magnetic resonance. In this way entangled states of electron spins corresponding to nitrogen-vacancy centres and nuclear spins corresponding to atomic nuclei having non-zero nuclear spin have been demonstrated. The electron spins of nitrogen-vacancy centres can be optically polarized and this polarization can be transferred to the nearby nuclear spins as they can be coupled. The electron spin state of single nitrogen-vacancy centre can be read out optically and as the electron and nuclear spins can be coupled, this readout has been used to demonstrate readout of single nuclear spins.

To build a useful nitrogen-vacancy centre quantum computer it will be necessary to controllably entangle nitrogen-vacancy centres. This has been demonstrated for two nitrogen-vacancy centres in different cryostats using optical entanglement by the group of R. Hanson at Delft University of Technology (P. C. Humphreys et al.: “Deterministic delivery of remote entanglement on a quantum network”, Nature 558, 268 (2018)), but the fidelity and the entanglement rate should be increased for useful quantum computing. In addition, many more than two nitrogen-vacancy centres will be needed and it would be impractical for them all to be in separate cryostats. Having as many nitrogen-vacancy centres as possible in one diamond would be valuable. By increasing the spin-photon coupling between a nitrogen-vacancy centre spin and the emitted photon fluorescence from it, improved optical entanglement fidelity and rate for two nitrogen-vacancy centres can be obtained. The main way to achieve this is with an optical cavity. There have been many unsuccessful designs for this.

### SUMMARY

According to a first aspect of the present invention, there is provided a system for quantum information processing comprising a body of material having first and second opposite faces, and at least one two-dimensional array of defects embedded in the body of material at a depth of between 0.2 μm and 6 μm from the first face.

The defects are either vacancy centres, donor atoms, or defects involving carbon atoms in silicon. The defects depend on the body of material (“host material”) selected. The defects are for providing qubits. The spin state of an electron corresponding to a defect may be used to store quantum information. In this way, the defect provides a qubit.

This depth range can allow some of the defects to have an electron spin coherence time, T₂, of at least 300 μs. For example, some of the nitrogen-vacancy centres may have an electron spin coherence time equal to or greater than 600 μs.

The material may be an insulator, semiconductor, or semiconductor alloy.

A spin state of an electron corresponding to a defect may be programmable to store quantum information.

The defects may be vacancy centres.

The material may be a single-crystal diamond membrane.

The vacancy centres may be negatively charged silicon vacancy centres, germanium vacancy centres, tin vacancy centres, or lead vacancy centres.

The body of material may be single-crystal silicon, single-crystal silicon carbide, zinc oxide, gallium nitride, amorphous silicon dioxide, or rare-earth-doped laser crystals.

The rare-earth-doped laser crystal may be Y₂SiO₅ doped with ions of europium, neodymium, and/or erbium.

Wherein the body of material is silicon carbide, the vacancy centres may be silicon vacancy centres or complex vacancy centres.

The body of material may be a single-crystal diamond membrane and the vacancy centres may be nitrogen-vacancy centres.

The system may further comprise an additional atomic nucleus having a non-zero nuclear spin disposed within 2 nm of a nitrogen-vacancy centre in the array, the nitrogen-vacancy centre having a corresponding electron spin, such that quantum information is transferred between the nuclear spin and the electron spin by hyperfine coupling.

The at least one two-dimensional array of nitrogen-vacancy centres may comprise between 10 and 10 million nitrogen-vacancy centres.

The at least one two-dimensional array may be contained within an area of between 0.01 mm² and 2500 mm².

The defects may be donors.

The material may be silicon carbide and the donors may be vanadium atoms.

The material may be silicon and the donors may be one of neutral phosphorous, bismuth, arsenic, or antimony donors.

Wherein the material is silicon, the defects may be involving carbon atoms provided in the silicon, for example G centre, T centre, I centre, M centre or W centre defects.

According to a second aspect of the present invention, there is provided an apparatus comprising the system of the first aspect, first and second optical reflectors between which the system is interposed, the first and second optical reflectors configured to form microcavities tuned into resonance or near-resonance with at least one optical transition of the vacancy centres, and at least one antenna configured to apply a magnetic field to control electron spin states corresponding to vacancy centres.

One or both of the optical reflectors may be a distributed Bragg reflector or a diamond surface or a metallic layer or any other engineered reflector.

The apparatus may further comprise a tuning layer between the optical reflectors.

The tuning layer may be a layer of a material that displays the linear electro-optic effect, such that the refractive index can be modified by application of an electric field, and/or the tuning layer may be a layer of a material that changes in thickness in response to an applied stimulus, for example, application of an electric field, optical or electron beam irradiation, or a current or a physical force, and/or the tuning layer may be a layer of a phase-change material having a refractive index that is modifiable by laser processing or thermal treatment.

According to a third aspect of the present invention, there is provided a method of fabricating the system for quantum information processing according to the first aspect, the method comprising, wherein the defects are vacancy centres: creating vacancies in a sample of material having an initial surface by laser processing, electron irradiation, ion implantation, atom implantation, or neutron irradiation, forming vacancy centres in the sample of material by thermal annealing or laser-induced vacancy diffusion, and etching the initial surface of the sample of material to fabricate the system.

The method may further comprise creating vacancies by laser processing, wherein the laser processing comprises applying laser pulses to a plurality of sites to form at least one two-dimensional array of vacancy centres embedded in the sample of material.

According to a fourth aspect of the present invention, there is provided a method of operating the system for quantum information processing according to the first aspect comprising, wherein the defects are vacancy centres: setting the electron spins corresponding to the vacancy centres to an initial state using optical illumination, manipulating the electron spins using magnetic pulses to perform quantum logic, and reading out the spin states of the vacancy centres based on measurement of at least one optical transition.

The method may further comprise creating entanglement between the electron spins of the vacancy centres using a projective readout method.

The method may further comprise transferring quantum information by hyperfine coupling between the nuclear spin of the additional atomic nucleus and the electron spin of the nitrogen-vacancy centre that the additional atomic nucleus is disposed within 2 nm of.

The method may further comprise cooling the system to less than 30 K.

According to a fifth aspect of the present invention, there is provided a system for quantum information processing comprising a single-crystal diamond membrane having first and second opposite faces, and at least one two-dimensional array of nitrogen-vacancy centres embedded in the diamond membrane at a depth of between 0.2 μm and 6 μm from the first faces.

This depth range can allow some of the nitrogen-vacancy centres to have an electron spin coherence time, T₂, of at least 300 μs. For example, some of the nitrogen-vacancy centres may have an electron spin coherence time equal to or greater than 600 μs.

This depth range can also allow some of the nitrogen-vacancy centres to have at least one optical transition with a spectral linewidth of less than 200 MHz.

Thus, the system may provide an improved memory component in a quantum processing apparatus.

The proportion of nitrogen-vacancy centres in the diamond membrane that exhibit these properties may be at least 10%.

The diamond membrane may have a thickness between 0.4 μm and 50 μm, for example between 1 μm and 20 μm, such as 5 μm.

The at least one two-dimensional array of nitrogen-vacancy centres embedded in the diamond membrane may be at a depth of between 0.2 μm and 4 μm from the first face.

The at least one two-dimensional array may be a plurality of two-dimensional arrays of nitrogen-vacancy centres arranged to form a three-dimensional array, or a plurality of three-dimensional arrays, of nitrogen-vacancy centres.

The system may further comprise an additional atomic nucleus having a non-zero nuclear spin disposed within 2 nm of a nitrogen-vacancy centre in the array, the nitrogen-vacancy centre having a corresponding electron spin, such that quantum information is transferred between the nuclear spin and the electron spin by hyperfine coupling.

The additional atomic nucleus may be a carbon-13 nucleus, a nitrogen-14 nucleus, a nitrogen-15 nucleus, a phosphorus-31 nucleus, a silicon-29 nucleus, or another atomic nucleus having non-zero nuclear spin.

The system may include a distribution of electron spins corresponding to nitrogen-vacancy centres and nuclear spins corresponding to additional atomic nuclei disposed within 2 nm of a nitrogen vacancy centre. The distribution may be engineered to minimise the magnetic noise experienced by qubits.

The at least one two-dimensional array may comprise between 10 and 10 million nitrogen-vacancy centres.

The at least one two-dimensional array may be contained within an area of between 0.01 mm² and 2500 mm².

For example, the at least one two-dimensional array may have dimensions of 10 mm×10 mm.

At least one of the first face and the second face may have an array of features aligned with the array of nitrogen vacancy centres.

The array of features aligned with the array of nitrogen vacancy centres may create or assist in the creation of optical microcavities.

At least one of the first face and the second face may be flat, or at least one of the first face and the second face may be convex and may have a radius of curvature that is greater than the thickness of the diamond membrane and less than 25 μm.

The system may comprise at least one electrode configured to allow at least one optical transition of a nitrogen-vacancy centre to be tuned by Stark tuning.

The at least one electrode may take the form of a laser-written wire configured to transmit RF and microwave excitations to a nitrogen-vacancy centre for spin control of the electron spin corresponding to that nitrogen-vacancy centre. This is useful as it means that wires can be written in three dimensions to be in the correct place for addressing nitrogen-vacancy centres in the at least one two-dimensional array.

According to a sixth aspect of the present invention, there is provided an apparatus comprising the system according to the first aspect of the invention, first and second optical reflectors between which the system is interposed, the first and second optical reflectors configured to form microcavities tuned into resonance or near-resonance with at least one optical transition of the nitrogen-vacancy centres, and at least one antenna configured to apply a magnetic field to control electron spin states corresponding to nitrogen-vacancy centres.

The magnetic field may be fixed. The magnetic field may be alternating.

The microcavities may be Fabry-Pérot microcavities.

Qubits may be created by applying electric and/or magnetic fields to the electron spins corresponding to the nitrogen-vacancy centres.

The apparatus may also include a light source for providing optical illumination. The optical illumination may be used to initialise the electron spin states of the nitrogen-vacancy centres. The light source may be coupled to control circuitry configured to control the light source.

Quantum logic may be performed by using magnetic pulses to manipulate spin states. The magnetic pulses may be applied with the antennae.

The apparatus may also include a detector for reading out the spin states of nitrogen-vacancy centres based on measurement of at least one optical transition.

The apparatus may be used to create entanglement between the spin states of nitrogen-vacancy centres using a projective readout method.

The apparatus may also include control circuitry coupled the diamond membrane.

One or both of the optical reflectors may be a distributed Bragg reflector or a diamond surface or a metallic layer or any other engineered reflector.

One or both of the optical reflectors may be in direct contact with the first face and the second face of the diamond membrane to form a monolithic cavity.

The apparatus may further comprise a tuning layer between the optical reflectors.

The tuning layer may be a layer of a material that displays the linear electro-optic effect, such that the refractive index can be modified by application of an electric field, and/or the tuning layer may be a layer of a material that changes in thickness in response to an applied stimulus, for example, application of an electric field, optical or electron beam irradiation, or a current or a physical force, and/or the tuning layer may be a layer of a phase-change material having a refractive index that is modifiable by laser processing or thermal treatment.

The antennae may be arranged in a grid aligned with the at least one two-dimensional array of nitrogen-vacancy centres.

According to a seventh aspect of the present invention, there is provided a method of fabricating the system for quantum information processing according to the first aspect of the present invention. The method comprises creating vacancies in a sample of diamond having an initial surface by laser processing, electron irradiation, ion implantation, atom implantation, or neutron irradiation. The method further comprises forming nitrogen-vacancy centres in the sample of diamond by thermal annealing or laser-induced vacancy diffusion, and etching the initial surface of the sample of diamond to fabricate the system.

The sample of diamond may be supported or unsupported. The sample of diamond may be a thin portion of diamond that is supported within a framework of thicker diamond.

The sample of diamond may have an initial nitrogen concentration below 1 nitrogen atom per million carbon atoms.

The sample of diamond may be etched to remove polish damage prior to vacancy generation.

The method may further comprise creating vacancies by laser processing, wherein the laser processing comprises applying laser pulses to a plurality of sites to form at least one two-dimensional array of nitrogen-vacancy centres embedded in the sample of diamond.

The laser pulses may be applied at a spacing of between 2 μm and 50 μm within the sample of diamond. The laser pulses may be applied at a depth of between 1 μm and 20 μm from the initial surface. For example, the laser pulses may be applied at a spacing of 5 μm and at a depth of 5 μm from the initial surface.

The laser pulses may have a wavelength between 500 nm and 1100 nm. For example, the laser pulses may have a wavelength of 790 nm.

The laser pulses may have a duration of less than one picosecond. The laser pulses may have a duration of between 250 fs and 350 fs. For example, the laser pulses may have a duration of 300 fs.

The method may comprise forming nitrogen-vacancy centres in the sample of diamond by thermal annealing at a temperature between 600° C. and 1,500° C. for a duration of between 1 and 8 hours.

The thermal annealing may be performed at a temperature of 1000° C. The duration of the thermal annealing may be 3 hours.

The method may comprise forming nitrogen-vacancy centres in the sample of diamond by laser-induced vacancy diffusion, the vacancy diffusion stimulated by one or more laser pulses.

The method may further comprise monitoring formation of nitrogen-vacancy centres at a site that is stimulated by one or more laser pulses, the monitoring based on measuring fluorescence from the site.

The method may further comprise stopping the application of laser pulses to the site when a pre-determined amount of nitrogen-vacancy centres have been formed, as determined by the monitoring based on measuring fluorescence from the site.

The etching may be plasma-assisted etching.

The etching may include a plurality of etching steps, for example, chlorine/argon plasma etching followed by oxygen plasma etching. The duration of the chlorine/argon plasma etching may be between 60 and 500 minutes. The duration of the oxygen plasma etching may be between 20 and 150 minutes.

The sample of diamond may be cleaned by acid cleaning prior to etching. The sample of diamond may be rinsed with acetone and iso-propanol after acid cleaning.

The method may further comprise forming features on the initial surface prior to etching.

To produce the apparatus according to the second aspect of the invention, the method of the third aspect of the invention may be extended to include depositing or otherwise affixing a tuning layer and/or one or more optical reflectors and/or an anti-reflection coating to the diamond membrane. Further, the method of the third aspect of the invention may include mounting the diamond membrane on to a base containing electrical wires and circuits for the generation of direct and alternating electric and magnetic fields.

According to a eighth aspect of the present invention, there is provided a method of operating the system for quantum information processing of the first aspect of the present invention. The method comprises setting the electron spins corresponding to the nitrogen-vacancy centres to an initial state using optical illumination, manipulating the electron spins using magnetic pulses to perform quantum logic, and reading out the spin states of the nitrogen-vacancy centres based on measurement of at least one optical transition.

Qubits may be created by applying electric and/or magnetic fields to the electron spins corresponding to the nitrogen-vacancy centres.

The method may further comprise creating entanglement between the electron spins of the nitrogen-vacancy centres using a projective readout method.

The method may be a method of operating the system of the first aspect and the method may further comprises transferring quantum information by hyperfine coupling between the nuclear spin of the additional atomic nucleus and the electron spin of the nitrogen-vacancy centre that the additional atomic nucleus is disposed within 2 nm of.

The method may further comprise cooling the system to less than 30 K.

For example, the method may include cooling the system to between 3 K and 7 K. For example, the method may include cooling the system to 4 K.

### BRIEF DESCRIPTION OF DRAWINGS

Certain embodiments of the present invention will now be described, by way of example, with reference to the accompanying drawings, in which:

FIG. 1 is a cross-sectional view of a system for quantum information processing;

FIG. 2 is a plan view of a system for quantum information processing;

FIG. 3 is a plan view of a system for quantum information processing;

FIG. 4 schematically illustrates an apparatus including a system for quantum information processing;

FIG. 5 is a schematic block diagram of an apparatus including a system for quantum information processing;

FIG. 6 is a process flow diagram of a method of fabricating a system for quantum information processing;

FIG. 7 is a process flow diagram of a method of operating a system for quantum information processing;

FIG. 8 is a process flow diagram of a method of operating a system for quantum information processing;

FIG. 9 is an energy level diagram of a nitrogen-vacancy centre; and

FIG. 10 is a process flow diagram of a method of operating a system for quantum information processing.

### DETAILED DESCRIPTION

In the following, like parts are denoted by like reference numerals.

The present application is concerned with a system for quantum information processing, the system including defects that can be used to provide qubits for quantum processing.

The system includes a host material into which are embedded (or “positioned” or “provided”) the defects. As will be hereinafter explained, the defects are vacancy centres, for example nitrogen-vacancy centres, donors implanted into the host material, or defects involving carbon atoms in silicon. The spin of an electron of a donor atom can be used to provide a qubit in a similar way to the electron spin of a vacancy centre.

The host material is in the form a body of material (also known as a “volume of material” or a “mass of material”). As will be hereinafter explained, the body of material has first and second opposite faces. However, it should be appreciated that the body of material may take any shape having first and second opposite faces.

The system for quantum information processing according to the present invention provides an improved memory component in a quantum processing apparatus. As an example, one promising way of achieving improved optical entanglement fidelity and rate for two nitrogen-vacancy vacancy centres is to have nitrogen-vacancy centres in a single crystal diamond around 5 μm thick, and to put this into an optical cavity formed from two mirrors separated by a little over 5 μm.

The host material is an insulator, semiconductor or semiconductor alloy.

In a preferred example, the host material is single-crystal diamond (herein also referred to as a “single-crystal diamond membrane”) and the defects embedded in the host material are nitrogen-vacancy centres.

Other defects in diamond are known to be useful for providing qubits. Other examples of vacancy centres to be used in single crystal-diamond include negatively charged silicon vacancy centres (SiV−), germanium vacancy centres (GeV−), tin vacancy centres (SnV−), and lead vacancy centres (PbV−). As will be explained hereinafter, these vacancy centres in diamond can be formed using laser writing or irradiation with electrons, ions, protons, or neutrons.

As hereinbefore stated, single-crystal diamond is a preferred example of the host material. However, any insulator, semiconductor, or semiconductor alloy may be used as the host material provided that that the material has less than 1% of atoms with dangling bonds. This is because dangling bonds have an electron spin and the presence of too many of these can adversely affect the spin coherence of spin qubits. Examples of unsuitable materials include unpassivated amorphous silicon, due to its high density of dangling bonds. Metallic materials would also be unsuitable because of their conduction electrons which also have an electron spin.

Examples of suitable insulators that can be used as the host material include single-crystal diamond, crystalline or amorphous silicon dioxide (SiO₂).

Examples of suitable semiconductors that can be used as the host material include group IV semiconductors such as single-crystal silicon (Si), single-crystal silicon carbide (SiC), and germanium (Ge). The following SiC polytypes may be used as the host material: 3C-SiC, 4H-SiC, and 6H-SiC, although other SiC polytpes could be used.

Other examples of suitable semiconductors that can be used as the host material include III-V semiconductors such as aluminium antimonide (AlSb), aluminium arsenide (AlAs), aluminium nitride (AlN), aluminium phosphide (AP), boron nitride (BN), non-hexagonal boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), and indium phosphide (InP).

Other examples of suitable semiconductors include II-VI semiconductors such as cadmium selenide (CdSe), cadmium sulfide (CdS), cadmium telluride (CdTe), zinc oxide (ZnO), zinc selenide (ZnSe), zinc sulfide (ZnS), and zinc telluride (ZnTe).

Examples of suitable semiconductor alloys that can be used as the host material include III-V ternary semiconductors alloys, such as aluminium gallium arsenide (AlGaAs, AlxGa₁₋ₓAs), indium gallium arsenide (InGaAs, InxGa₁₋ₓAs), indium gallium phosphide (InGaP), aluminium indium arsenide (AlInAs), aluminium indium antimonide (AlInSb), gallium arsenide nitride (GaAsN), gallium arsenide phosphide (GaAsP), aluminium gallium nitride (AlGaN), aluminium gallium phosphide (AlGaP), indium gallium nitride (InGaN), indium arsenide antimonide (InAsSb), and indium gallium antimonide (InGaSb).

Other examples of suitable semiconductors alloys include III-V quaternary semiconductors alloys, such as aluminium gallium indium phosphide (AlGaInP also known as InAlGaP, InGaAlP or AlInGaP), aluminium gallium arsenide phosphide (AlGaAsP), indium gallium arsenide phosphide (InGaAsP), aluminium indium arsenide phosphide (AlInAsP), aluminium gallium arsenide nitride (AlGaAsN), indium gallium arsenide nitride (InGaAsN), indium aluminium arsenide nitride (InAlAsN), and gallium arsenide antimonide nitride (GaAsSbN).

Other example host materials include silicon nitride (SiN) and amorphous silica.

Silicon carbide may be preferable because this material can be used in the form of a large wafer, unlike single-crystal diamond.

Suitable vacancy centres may be embedded into any one of the insulator, semiconductor, or semiconductor alloy host materials hereinbefore outlined. Examples of these vacancy centres may include negatively charged silicon vacancy centres (SiV−), germanium vacancy centres (GeV−), tin vacancy centres (SnV−), lead vacancy centres (PbV−), negatively charged nitrogen-vacancy centres (NV−).

In an example in which SiC is the host material, the defects embedded into SiC may be silicon vacancy centres (VSi), complex vacancies such as carbon anti-site vacancy pairs (CAV), and divacancies (VV). The vacancies can be created with laser writing, or irradiation with electrons, ions, protons, or neutrons. Annealing can then be used to create spin qubits. Alternatively, the defects embedded in SiC may be vanadium dopants.

In an example in which silicon is the host material, suitable defects include donors such as neutral phosphorous, bismuth, arsenic, antimony donors, positively charged selenium, and sulphur donors.

Donors are typically grown in or made with ion implantation followed by annealing. Donor may be formed in the host material using the same or similar methods as described herein for vacancy centres. Donors providing qubits may be controlled/excited in a similar way to vacancy centres providing qubits as described herein, i.e. by optical excitation, microwave spin control and optical readout.

In another example where silicon is the host material, other defects that could be used include G centre, T centre, I centre, M centre and W centre. These centres are defects involving carbon atoms in silicon. These defects may be observed after radiation damage of the silicon. 28Si isotopic purification can increase the spin and optical coherence, giving sharper resonances, improving the control that is possible.

The precise microscopic structure of the G centre in silicon is still not agreed on, but it is widely thought to be a pair of carbon atoms bridging an interstitial silicon atom, with a carbon-silicon-carbon angle of 126 degrees. The photoluminescence has a sharp zero-phonon line at around 1270 nm with a broad phonon sideband.

The precise microscopic structure of the T centre in silicon is not agreed on, but it has been proposed that it is two bonded carbon atoms, one of which is bonded to a hydrogen atom. It is thought that an interstitial C—H defect binds with a substitutional C atom.

These centres (defects involving carbon atoms in silicon) providing qubits may be controlled/excited in a similar way to vacancy centres providing qubits as described herein. These centres may be formed by ion implanting or neutral atom implanting with carbon.

### System 1 for Quantum Information Processing

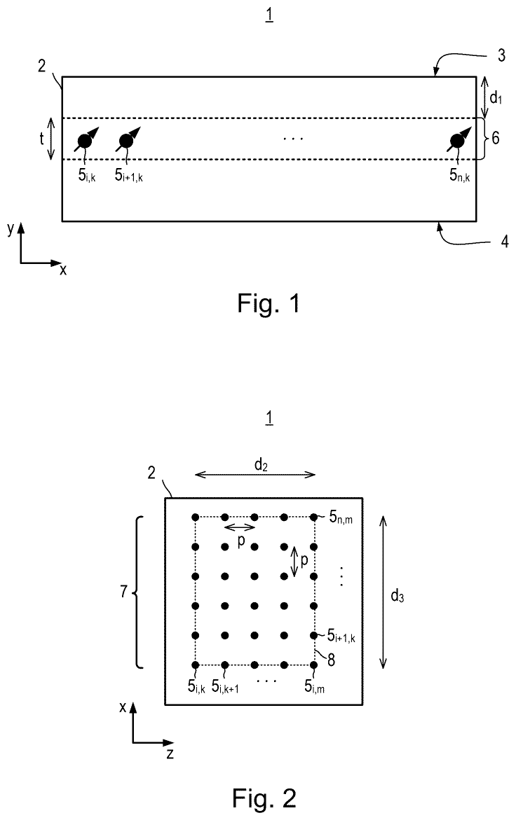

Referring to FIG. 1, a first system 1 for quantum information processing (herein also referred to as a “system”) is shown.

The first system 1 is an example system for quantum information processing which includes a single-crystal diamond membrane 2 as the host material (or “body of material”) and nitrogen-vacancy centres as the defects.

The first system 1 includes the single-crystal diamond membrane 2 having a first surface 3 (herein also referred to as “first face”) and second surface 4 (herein also referred to as “second face”) opposite to the first surface 3. At least one two-dimensional array of nitrogen-vacancy centres 5_{i,k}, 5_{i+1,k}, 5_{i,k+1} . . . 5_{n,m} are embedded in the diamond membrane 2. The nitrogen-vacancy centres 5_{i,k}, 5_{i+1,k}, 5_{i,k+1} . . . 5_{n,m} are embedded at a depth d, from the first surface 3, where 0.2 μm≤d₁≤6 μm.

This can allow some of the nitrogen-vacancy centres 5_{i,k}, 5_{i+1,k}, 5_{i,k+1} . . . 5_{n,m} to have an electron spin coherence time, T₂, of at least 300 μs, when the T₂ time is measured at 300 K by a Hahn Echo measurement. This can allow some of the nitrogen-vacancy centres 5_{i,k}, 5_{i+1,k}, 5_{i,k+1} . . . 5_{n,m} to have at least one optical transition with a spectral linewidth of less than 200 MHz. Thus, the first system 1 may provide an improved memory component in a quantum processing apparatus.

Preferably the proportion of nitrogen-vacancy centres in the diamond membrane 2 that exhibit these properties is at least 10%.

In particular, the nitrogen-vacancy centres 5_{i,k}, 5_{i+1,k}, 5_{i,k+1} . . . 5_{n,m} can be used to store quantum information (as “qubits”). A nitrogen-vacancy centre consists of a nitrogen atom-lattice vacancy pair. An electron at the lattice vacancy site has a spin state (herein also referred to as “electron spin state” of the nitrogen-vacancy centre). As will be hereinafter explained, the electron spin can be switched between different states so as to provide a qubit.

In some examples, some of the nitrogen-vacancy centres 5_{i,k}, 5_{i+1,k}, 5_{i,k+1} . . . 5_{n,m} have an electron spin coherence time, T₂, of at least 600 μs, when the T₂ time is measured at 300 K by a Hahn Echo measurement.

The thickness of the diamond membrane 2 may be between 0.4 μm and 50 μm, for example between 1 μm and 20 μm, such as 5 μm. In some examples, 0.2 μm≤di≤4 μm.

The nitrogen-vacancy centres 5_{i,k}, 5_{i+1,k}, 5_{i,k+1} . . . 5_{n,m} are arranged in a layer 6 having a thickness t within the diamond membrane 2. The thickness t of the layer 6 may be between 1 nm and 5000 nm.

Referring also to FIG. 2, a plan view of the first system 1 is shown.

The two-dimensional array 7 is shown to be a square array in which nitrogen-vacancy centres 5_{i,k}, 5_{i+1,k}, 5_{i,k+1} . . . 5_{n,m} are separated by a spacing p. However, the nitrogen-vacancy centres 5_{i,k}, 5_{i+1,k}, 5_{i,k+1} . . . 5_{n,m} may be arranged in any array pattern. The array pattern chosen may depend on factors such as the design of electrical wiring implemented in the first system 1 and the desired area density of qubits. In alternative implementations, the nitrogen-vacancy centres 5_{i,k}, 5_{i+1,k}, 5_{i,k+1} . . . 5_{n,m} may be arranged spaced apart along a path, for example a spiral or serpentine path.

The array 7 is contained within a region 8 having an area d₂×d₃ of the diamond membrane 2. In some examples, the region 8 has an area d₂×d₃ between 0.01 mm² and 2500 mm². For example, the at least one two-dimensional array may have dimensions of 10 mm×10 mm.

The single-crystal diamond membrane 2 may include more than one two-dimensional array 7. In some examples, two-dimensional arrays 7 may be arranged in different regions of the diamond membrane 2, each in a layer embedded at a depth d, from the first surface 3. In other examples, two-dimensional arrays 7 may be arranged to form a three dimensional array in the same region 8 having area d₂×d₃ of the diamond membrane 2. In other examples, the arrays 7 may be arranged to form three dimensional arrays in different regions of the diamond membrane 2.

The at least one two-dimensional array 7 may include between 10 and 10 million nitrogen-vacancy centres 5_{i,k}, 5_{i+1,k}, 5_{i,k+1} . . . 5_{n,m}.

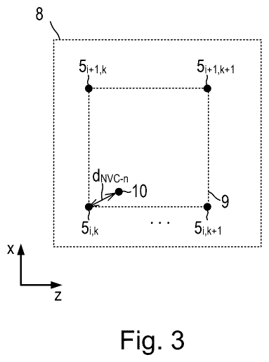

Referring also to FIG. 3, a plan view of a part 9 of the region 8 of the first system 1 is shown.

In some examples, the part 9 of the region 8 may include an additional atomic nucleus 10 having a non-zero nuclear spin disposed within a distance d_{NVC-n} of 2 nm of a given nitrogen-vacancy centre 5_{i,k} having a corresponding electron spin in the array 7. This can allow quantum information to be transferred between the nuclear spin of the nitrogen-vacancy centre 5_{i,k} and the additional atomic nucleus 10 by hyperfine coupling.

The additional atomic nucleus can be any atomic nucleus having non-zero nuclear spin. For example, the additional atomic nucleus may be a carbon-13 nucleus, a nitrogen-14 nucleus or a nitrogen-15 nucleus, a phosphorus-31 nucleus, or a silicon-29 nucleus. Additional nitrogen nuclei typically form a part of the nitrogen-vacancy centre, whereas useful carbon-13 nuclei are typically less than 2 nm from the nitrogen-vacancy centre.

In some examples, more than one additional atomic nuclei is disposed within 2 nm of one nitrogen-vacancy centre 5_{i,k} in the array 7. In other examples, more than one of the nitrogen-vacancy centres 5_{i,k}, 5_{i+1,k}, 5_{i,k+1} . . . 5_{n,m} in the array 7 have a corresponding additional atomic nucleus disposed within a distance of 2 nm. The first system 1 may include a distribution of electron spins corresponding to nitrogen-vacancy centres and nuclear spins corresponding to additional atomic nuclei disposed within 2 nm of a nitrogen vacancy centre, and this distribution may be engineered to minimise the magnetic noise experienced by qubits.

Thus, the spin of additional atomic nuclei having a non-zero nuclear spin proximate to the nitrogen-vacancy centre 5_{i,k} can also provide a qubit.

The first surface 3 and the second surface 4 of the diamond membrane 2 may be planar, or may include non-planar features designed to facilitate enhanced optical coupling to the nitrogen-vacancy centres.

In some examples, at least one of the first surface 3 and the second surface 4 is flat. In other examples, at least one of the first surface 3 and the second surface 4 is convex and has a radius of curvature that is greater than a thickness of the diamond membrane 2 and less than 25 μm.

Further, at least one of the upper surface 3 and the lower surface 4 may have an array of features aligned with the at least one array 7 of nitrogen-vacancy centres 5_{i,k}, 5_{i+1,k}, 5_{i,k+1} . . . 5_{n,m}. This can help to create or assist in the creation of optical microcavities when the diamond membrane 2 is incorporated into an apparatus including reflectors.

At least one of the upper surface 3 and the lower surface 4 may include non-planar features designed to facilitate enhanced optical coupling to nitrogen-vacancy centres. These surfaces may additionally be coated with highly reflective or anti-reflection coatings, or some combination of these, to further facilitate enhanced optical coupling to nitrogen-vacancy centres.

The first system 1 may also include at least one electrode configured to allow the at least one optical transition to be tuned by Stark tuning. The at least one electrode may be disposed on either the first surface 3 or the second surface 4, or disposed within the diamond membrane 2.

In some implementations, the at least one electrode may take the form of a wire soldered across either the first surface 3 or the second surface 4 that is configured to provide microwave radiation to the array 7. It was found when the at least one electrode takes the form of a wire is disposed within 100 μm of the nitrogen vacancy centres, magnetic resonance can be excited and experienced by the nitrogen vacancy centres 5_{i,k}, 5_{i+1,k}, 5_{i,k+1} . . . 5_{n,m} and any additional nuclei 10. The wire may be a copper wire or a gold wire. The wire may have a width of between 10 μm and 30 μm, for example 20 μm.

As will be hereinafter explained, the wire is configured to provide microwave radiation to array(s) 7 of nitrogen-vacancy centres 5_{i,k}, 5_{i+1,k}, 5_{i,k+1} . . . 5_{n,m}. However, it is not required that the at least one electrode takes the form of a wire that is soldered. For example, the wire may be deposited directly onto the diamond membrane 2 using photolithography. In another example, the wire may be deposited onto a separate substrate (not shown) to which the diamond membrane 2 is then attached.

The at least one electrode may include at least one metal layer. To provide the metal contacts, the metal layer(s) is coated in positive photoresist and photolithography is used to form the metal contacts.

In other implementations, the at least one electrode may take the form of a laser-written wire configured to transmit radiofrequency (herein also referred to as “RF”) and microwave excitations to a nitrogen-vacancy centre for spin control of the electron spin corresponding to that nitrogen-vacancy centre. This is useful as it means that wires can be written in three dimensions to be in the correct place for addressing nitrogen-vacancy centres in the at least one two-dimensional array 7. Thus, microwave excitation can be supplied selectively so that a chosen electron spin in the array 7 experiences magnetic resonance. Likewise, RF excitation can be supplied so that a chosen nuclear spin of an additional nucleus experiences magnetic resonance. In alternative implementations, the at least one electrode may take the form of a wire written by a focussed ion beam that is otherwise similar to the laser-written wire hereinbefore described.

It has been found that Stark shifting using non-laser-written wires can make the emission wavelength of two nitrogen-vacancy centres indistinguishable, which is useful as this is required to create optical entanglement. It has also been found that laser-written wires conduct electricity at helium temperatures (1 to 10 K) so can be used for Stark shifting for optical entanglement in this temperature range.

As hereinbefore explained, other vacancy centres may be used in the single-crystal diamond membrane 2 instead of nitrogen vacancy centres.

A second system (not shown) for quantum processing includes an at least one two-dimensional array, as hereinbefore described, but consisting vacancy centres other than NV− centres, such as SiV−, GeV−, SnV−, or PbV− centres. This second system is similar to the first system 1.

Other examples (not shown) of the system for quantum processing use the alternative host materials and suitable defects hereinbefore described. These example systems are similar to the first system 1.

### Apparatus 10 for Quantum Information Processing

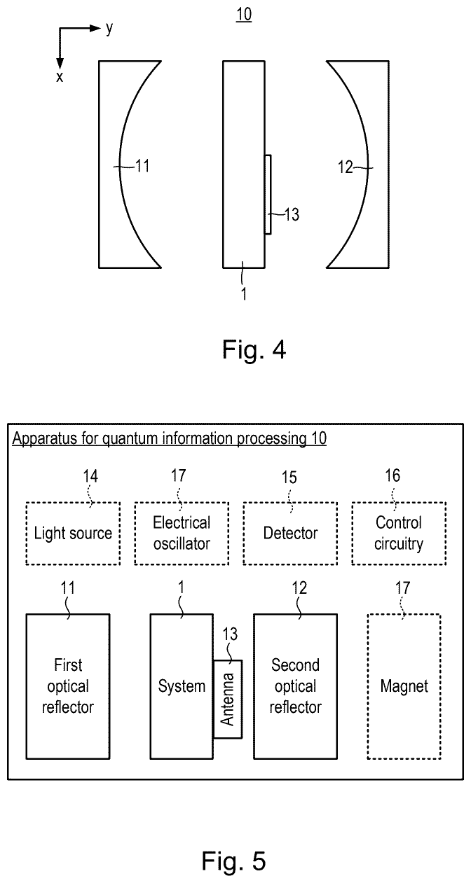

Referring to FIG. 4, an apparatus for quantum information processing 10 (herein also referred to as an “apparatus”) is shown.

The apparatus 10 includes the first system 1, first and second optical reflectors 11, 12 spaced apart in the horizontal direction between which the first system 1 is interposed, and at least one antenna 13 configured to apply a magnetic field to control electron spin states corresponding to nitrogen-vacancy centres 5_{i,k}, 5_{i+1,k}, 5_{i,k+1} . . . 5_{n,m}. The first and second optical reflectors 11, 12 are configured to form a microcavity tuned into resonance or near-resonance with at least one optical transition of the nitrogen-vacancy centres 5_{i,k}, 5_{i+1,k}, 5_{i,k+1} . . . 5_{n,m}. The at least one antenna 13 may apply a fixed magnetic field and/or an alternating magnetic field.

Qubits may be created by applying electric and/or magnetic fields to the electron spins corresponding to the nitrogen-vacancy centres 5_{i,k}, 5_{i+1,k}, 5_{i,k+1} . . . 5_{n,m}. Quantum logic may be performed by using magnetic pulses to manipulate spin states. The magnetic pulses may be applied with the at least one antenna 13.

The microcavities may be Fabry-Pérot microcavities. The microcavity enhances the coupling between electric dipole transitions in the nitrogen-vacancy centre and the surrounding optical environment at selected wavelengths. In this way, the microcavity can help to make a nitrogen-vacancy centres 5_{i,k}, 5_{i+1,k}, 5_{i,k+1} . . . 5_{n,m} emit fluorescence photons at the zero-phonon wavelength of 637 nm, or can help to provide for efficient conditional reflection of an incident photon dependent on the nitrogen-vacancy centre spin state. This enhancement in the coupling hereinbefore described can improve the rate of optical entanglement between the electron spin states corresponding to nitrogen-vacancy centres.

The first and second optical reflectors 11, 12 are shown as having curved faces. However, these faces may be curved or flat. The diamond membrane 2 is positioned between the first and second optical reflectors 11, 12 such that the array 7 is parallel to the vertical plane. In a preferred example, the faces of the first and second optical reflectors 11, 12 may each consist of an array of curved surfaces aligned with the array 7 of nitrogen-vacancy centres 5_{i,k}, 5_{i+1,k}, 5_{i,k+1} . . . 5_{n,m} in the diamond membrane 2. The face of one or both optical reflectors 11, 12 may consist of the array of curved surfaces aligned with the array 7.

One or both of first and second optical reflectors 11, 12 may be a distributed Bragg reflector or a diamond surface or a metallic layer or any other engineered reflector. One or both of first and second optical reflectors 11, 12 may be in direct contact with the first surface 3 and the second surface 4 of the diamond membrane 2 to form a monolithic cavity.

In some implementations, the apparatus 10 may comprise a tuning layer (not shown) between the first and second optical reflectors 11, 12. The tuning layer may be: a layer of a material that displays the linear electro-optic effect, such that the refractive index can be modified by application of an electric field; and/or a layer of a material that changes in thickness in response to an applied stimulus, for example, application of an electric field, optical or electron beam irradiation, or a current or a physical force; and/or a layer of a phase-change material having a refractive index that is modifiable by laser processing or thermal treatment.

In some examples, there may be two or more antennae 13, the two or more antennae arranged in a grid aligned with the at least one two-dimensional array 7 of nitrogen-vacancy centres 5_{i,k}, 5_{i+1,k}, 5_{i,k+1} . . . 5_{n,m}.

Referring also to FIG. 5, a schematic block diagram of the apparatus 10 is shown.

The apparatus 10 may also include a light source 14 configured to emit pulses of light to excite and/or switch the state of the nitrogen-vacancy centres 5_{i,k}, 5_{i+1,k}, 5_{i,k+1} . . . 5_{n,m} and a detector 15 configured to read out the spin states of nitrogen-vacancy centres 5_{i,k}, 5_{i+1,k}, 5_{i,k+1} . . . 5_{n,m} based on measurement of the at least one optical transition. The pulses of light may be used to initialise the electron spin states of the nitrogen-vacancy centres. The detector 15 may record emission spectra produced by the nitrogen-vacancy centres 5_{i,k}, 5_{i+1,k}, 5_{i,k+1} . . . 5_{n,m} of the first system 1.

The apparatus 10 may also include control circuitry 16 that is electrically coupled to the at least one electrode (not shown) hereinbefore described and, separately, to the light source 14. The control circuitry 13 is configured to drive a current through the wire (not shown) on or inside to the diamond article 1 such that an electromagnetic field is produced. This field can be microwave or radiofrequency or it can include both of these.

The apparatus 10 may further comprise an electrical oscillator 17 configured to emit radiofrequency pulses for controlling the spin state of a nucleus, as will be hereinafter described. The control circuity 16 is electrically coupled to the electrical oscillator 17.

The apparatus 10 may also include a magnet 17 for providing a magnetic field across the diamond article 1. The magnet 17 may be a permanent magnet and it may be mounted on an adjustable mount (not shown). The adjustable mount can allow for varying the strength of the magnetic field that the diamond article 1 is subjected to, and further helps to align the magnetic field to an axis of the nitrogen-vacancy centres 5_{i,k}, 5_{i+1,k}, 5_{i,k+1} . . . 5_{n,m} of the first system 1.

The apparatus may be used to create entanglement between the spin states of nitrogen-vacancy centres 5_{i,k}, 5_{i+1,k}, 5_{i,k+1} . . . 5_{n,m} using a projective readout method. Here, the projective readout method involves performing a measurement on a non-entangled state (or weakly entangled state) which will project it onto a state with a higher degree of entanglement. The process is probabilistic as entanglement is only created/improved for specific measurement outcomes. Critically the method is ‘heralded’ in that the measurement outcomes tell you when it has succeeded.

In an alternative example, the apparatus 10 may include the second system (not shown) instead of the first system 1.

In another example, the apparatus 10 may include an example system in which a host material other than single-crystal diamond is used and suitable defects are used to provide a qubit.

### Method of Fabrication

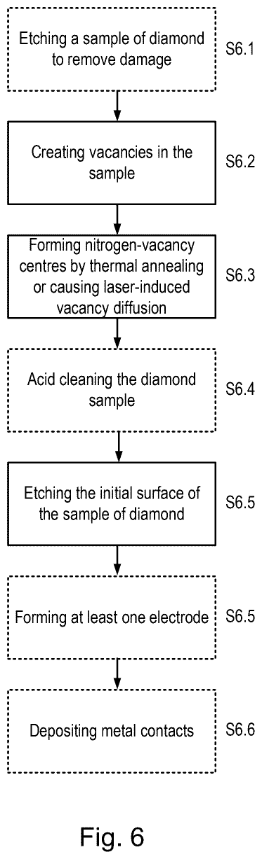

Referring to FIG. 6, a method of fabricating the first system 1 will now be described.

The first system 1 is fabricated from a sample of diamond.

The sample of diamond may be a single crystal chemical vapour deposition (CVD−) grown diamond having initial nitrogen concentration below 1 nitrogen atom per million carbon atoms. The sample of diamond may have a natural isotopic abundance of ¹³C or may be engineered to control the concentration and/or distribution of ¹³C isotopes, which can be useful because the ¹³C atoms have a nuclear spin which can act as additional qubits. Alternatively, the diamond can be isotopically enriched with ¹²C to reduce the noise due to the ¹³C spins. Furthermore, a diamond can be used which is isotopically enriched with ¹²C but has a ‘delta-doped’ layer of ¹³C to provide useful nuclear spins that are close to the nitrogen-vacancy centre but without the distant ¹³C nuclear spins which provide noise but are too far away to be usefully coupled. This delta-doped layer may have extra nitrogen to increase the chances of creating nitrogen-vacancy centres there. The sample of diamond may be supported or unsupported, and may be a single crystal diamond membrane window (SCDMW). The sample of diamond may be a thin portion of diamond that is supported within a framework of thicker diamond.

The sample of diamond may be etched to remove polish damage (step S6.1). The etch may be a plasma-assisted etch. The etch may remove 10 μm to 30 μm of subsurface damage, for example 20 μm.

As will be described hereinafter, nitrogen-vacancy centres 5_{i,k}, 5_{i+1,k}, 5_{i,k+1} . . . 5_{n,m} can be written into the sample of diamond having an initial surface by laser processing or other methods, then thermally annealing or causing laser-induced vacancy diffusion.

A step of laser processing (or alternative methods of electron irradiation, ion implantation, atom implantation, or neutron irradiation) creates vacancies in the sample of diamond (step S6.2). The step of thermally annealing or causing laser-induced vacancy diffusion forms nitrogen-vacancy centres in the sample of diamond (step 6.3). The step of etching the initial surface such that the nitrogen-vacancy centres 5_{i,k}, 5_{i+1,k}, 5_{i,k+1} . . . 5_{n,m} are embedded at a depth of between 0.2 μm and 6 μm from a first surface of the sample of diamond results in the first system 1 being fabricated (step S6.4).

In step S6.2, when vacancy creation is carried out by laser processing, a sequence of laser pulses is applied to the sample of diamond. One or more laser pulses may be applied to a plurality of sites in the sample. At each site, the laser pulse(s) damage the crystal lattice of the sample of diamond and a vacancy in the lattice is formed. The use of laser writing may help to minimise damage to the diamond sample compared to conventional methods of producing nitrogen-vacancy centres.

In a preferred example, each laser pulse applied to the sample of diamond has a wavelength of between 500 nm and 1100 nm. Each laser pulse may have a wavelength of between 700 nm and 800 nm, for example 790 nm. The laser pulses in the sequence of laser pulses may have a plurality of different wavelengths.

Each laser pulse may have a duration of less than 1 ps. For example, each laser pulse may have a duration between 100 fs and 500 fs, or between 250 fs and 350 fs, such as 300 fs.

The laser writing may be performed using single pulses of 790 nm for 300 fs per pulse. The sequence of laser pulses may be applied in a grid formation so as to produce at least one two-dimensional array of vacancies embedded in the sample of diamond.

Each laser pulse may be applied at a spacing of between 2 μm and 50 μm along an axial directions, for example the x direction or the z direction. Each laser pulse may be applied at a pitch of 5 μm. Each laser pulse may be applied into the initial surface at a depth of between 1 μm and 30 μm or between 1 μm and 20 μm, for example 5 μm. For example, each of the laser pulses may be applied at a spacing of 5 μm and at a depth of 5 μm from the surface.

Laser processing using pulses above the graphitisation threshold may also be used to create sub-surface graphitic wires within the diamond membrane 2. Graphitic wires allow for fine control of the electrical environment experienced by the arrays 7 of nitrogen-vacancy centres 5_{i,k}, 5_{i+1,k}, 5_{i,k+1} . . . 5_{n,m}. This can be useful for several reasons. One of these is controlling the charge state of the nitrogen-vacancy centre: typically, NV⁻ is used, but it can be useful to change to NV^{o} or NV⁺ for a period to increase the nuclear spin coherence time, and it can be useful to eject an electron from an NV⁻ so that the electron is captured by another nitrogen-vacancy centre in order to entangle them. Another use of laser-written wires is for Stark shifting the optical emission wavelength so as to make it indistinguishable from that of another nitrogen-vacancy centre such as for optical entanglement of the two nitrogen-vacancy centres. A third use of laser-written wires is for applying electromagnetic excitation for magnetic resonance.

Microwave excitation is generally used for the electron spins corresponding to nitrogen-vacancy centres and radiofrequency excitation is generally used for the additional nuclear spin(s) corresponding to additional atomic nuclei having non-zero nuclear spin. Just one of the nuclear spins could be used or any combination of multiple types. Typically, the microwave and the RF excitation would be used in the same device to allow control of both the electron and the nuclear spins. Both microwave and RF excitation can be sent in through the same wire, or different wires can be used.

As hereinbefore described, in step S6.2, vacancy creation can be carried out by electron irradiation instead of laser processing. Specifically, vacancy creation can be carried out by applying a sequence of pulses of focussed electron irradiation to an array of sites in a sample of diamond.

In step S6.3, nitrogen-vacancy centres are formed, at the sites where vacancies have been created, by either a thermal anneal of the entire diamond, or with laser-induced diffusion by focusing a laser beam onto a chosen laser-written site.

When nitrogen-vacancy centres are to be formed by thermal annealing, the sample of diamond may be buried in diamond grit, for example Element Six™ grit. The diamond grit may be in an alumina boat or container. Once submerged in the diamond grit, the diamond sample may be placed in a furnace (not shown), for example a tube furnace, and annealed.

Annealing may be performed at a temperature of between 600° C. and 1,500° C. for between 1 and 8 hours, such as 3 hours. In one example, annealing is performed at a temperature of 1,000° C. for 3 hours.

As hereinbefore stated, annealing produces the nitrogen-vacancy centres 5_{i,k}, 5_{i+1,k}, 5_{i,k+1} . . . 5_{n,m}. Specifically, annealing causes the vacancies to become mobile and migrate through the lattice of the diamond membrane 2. At least some of these vacancies encounter a nitrogen atom and form a stable nitrogen-vacancy centres 5_{i,k}, 5_{i+1,k}, 5_{i,k+1} . . . 5_{n,m}. After annealing, a majority of the sites at which laser processing (or an alternative method hereinbefore listed) was carried out in step S6.2 may be occupied by nitrogen-vacancy centres 5_{i,k}, 5_{i+1,k}, 5_{i,k+1} . . . 5_{n,m}.

Immediately prior to annealing, and during annealing, the furnace may be continuously purged with dry nitrogen boil-off to help minimise the levels of oxygen present in the furnace. This may help to limit the potential to cause oxidization and/or graphitisation of the surfaces of the sample of diamond.

Instead of a thermal anneal, a pulsed or continuous laser beam can be applied to impart or deposit energy at a site at which laser processing (or an alternative method hereinbefore listed) was carried out in step S6.3 to cause the atoms to diffuse until a vacancy finds a nitrogen atom forming a nitrogen-vacancy centre at said site. The fluorescence from the site can be continuously monitored during this process so that it can be stopped when the characteristic fluorescence of a given nitrogen-vacancy centre is detected as this indicates that said nitrogen-vacancy centre has been successfully formed. This laser diffusion technique is sometimes referred to as “laser annealing”. However, unlike conventional annealing, this laser diffusion technique is electronic in nature rather than thermal.

After annealing the diamond sample or using laser-induced diffusion to create nitrogen-vacancy centres, the surface of the sample may be acid cleaned to remove any accumulated surface contamination (step S6.4).

Acid cleaning may include a plurality of acid etching steps. After each acid etching step, the diamond sample may be rinsed with acetone and iso-propanol to help remove traces of the acid.

Acid cleaning may include etching the surface in piranha solution, then subsequently etching the surface in aqua regia. The etch in piranha solution may be for a duration of between 10 and 30 minutes, for example 20 minutes. The etch in piranha solution may help to remove any organic contaminants such as dirt or other organic matter from the surface. The etch in aqua regia may help to remove any metallic contaminants from the surface which may have been added in transport or from previous handling.

After annealing the diamond sample, and, optionally, acid cleaning the diamond sample, the surface of the diamond sample is etched (step S6.5). Following step S6.5, the first system 1 hereinbefore described is produced.

The type of etching selected may help to minimise the number of unbonded charges remaining on the surface following etching. The initial surface may be etched with a plasma-assisted etch, for example by inductively coupled plasma etching. The etching may include a plurality of etching steps.

Prior to etching, steps may be taken to fabricate a non-planar shape of the diamond surface, in other words, to form features on the initial surface. This might be achieved by ion beam milling or laser processing of the diamond surface prior to etching, or by masking the diamond surface in such a way that etching produces the desired shape.

The etching recipe used should create smooth surfaces with minimal residual damage to the diamond article. In one example, the surface of the diamond sample is etched using a mixture of chlorine and argon (herein also referred to as “Ar/Cl₂ etching”) in a first etching step. In the same example, the surface is etched in a second etching step using oxygen (“O₂ etching”). The surface may be Ar/Cl₂ etched for between 60 and 500 minutes, for example 86 minutes. The surface may be O₂ etched for between 20 and 150 minutes.

The initial surface is etched so that each nitrogen-vacancy centre 5_{i,k}, 5_{i+1,k}, 5_{i,k+1} . . . 5_{n,m}. is between 0.2 μm and 6 μm from the first surface 3 of the diamond membrane 2. The initial surface of the sample of diamond may be etched so that the diamond membrane 2 has a thickness of between 3 μm and 10 μm, for example 4 μm.

Etching the diamond sample may help to provide a system 1 that is thin enough to be placed in an optical cavity (see FIG. 4).

The combination of creating vacancies in the sample of diamond by laser processing (or an alternative method hereinbefore listed), forming nitrogen-vacancy centres in the sample of diamond by thermal annealing or causing laser-induced vacancy diffusion, and then etching the sample as hereinbefore described in steps S6.2, S6.3, and S6.5 can allow nitrogen vacancy centres 5_{i,k}, 5_{i+1,k}, 5_{i,k+1} . . . 5_{n,m} which have long coherence times, for example of at least 300 microseconds to be produced, the coherence time measured at room temperature for naturally isotopic diamond with a spin echo measurement but no dynamic decoupling. The spin coherence times may be even longer if the temperature is reduced and/or the diamond is isotopically purified to have more carbon-12, and/or if dynamical decoupling is used.

In other words, this method can allow for an improved system 1 for quantum information processing to be produced.

After etching the diamond sample, at least one electrode may be formed or otherwise affixed to either the first surface 3 or the second surface 4, or formed within the diamond membrane 2 (step S6.6). As described hereinbefore, the at least one electrode may take the form of a wire that is soldered to either the first surface 3 or the second surface 4, may be directly patterned onto the diamond membrane 2 using lithography, may take the form of a sub-surface graphitic wire formed by laser processing, or may be patterned onto a separate substrate to which the diamond membrane is then attached. The at least one electrode can allow microwave excitation to be supplied selectively so that a chosen electron spin in the array 7 experiences magnetic resonance. The at least one electrode can also allow RF excitation to be supplied so that a chosen nuclear spin of an additional nucleus experiences magnetic resonance.

As described hereinbefore, the at least one electrode may be deposited on either the first surface 3 or the second surface 4 by photolithography and the at least one electrode may include of a plurality of metal layers. In one example, a layer of titanium is provided on the surface of the diamond membrane 2, a layer of platinum is provided on the titanium layer, and a thicker layer of gold is provided on the layer of platinum. In this example, including the platinum layer can help to prevent the formation of titanium gold (Ti—Au), which can give inconsistent electrical connection between the at least one electrode and control circuitry. Each metal layer may be deposited via physical vapour deposition. The titanium layer and the platinum layer may be between 5 nm and 15 nm thick. The gold layer may be between 150 nm and 250 nm thick.

When the at least one electrode is a sub-surface graphitic wire, the method can be extended to include fabricating further electrodes on the first surface 3 or the second surface 4 that can allow an electrical contact to be made to sub-surface graphitic wire(s).

If metal deposition does not work satisfactorily and it is necessary to start it again, the first system 1 may be further etched to help remove any metal contaminants from the surface, such as titanium. This etching step may have a duration of between 1 and 3 minutes. The etching may involve an aqua regia etch followed by an etch in 1% hydrofluoric acid in water.

To produce the apparatus according to the second aspect of the invention, the method may be extended to include depositing or otherwise affixing a tuning layer and/or one or more optical reflectors and/or an anti-reflection coating to the diamond membrane 2. Further, the method may include mounting the diamond membrane 2 onto a base containing electrical wires and circuits configured generation of direct and alternating electric and magnetic fields and couple those fields to the at least one electrode.

The second system (not shown) may be fabricated in a similar way to the first system 1. Specifically, SiV−, GeV−, SnV−, and PbV− vacancy centres can be formed using laser writing. Alternatively, these vacancy centres can be formed using electron irradiation, ion implantation, atom implantation, or neutron irradiation.

Other systems (not shown) which include a host material other than single-crystal diamond, for example SiC, may be fabricated in a similar way to the first system 1. These other systems may include defects other than nitrogen-vacancy centres, as hereinbefore described.

The specific parameters for laser writing (or one of the alternative methods described) in step S62, annealing (or causing laser-induced vacancy diffusion) in step S6.3, and etching in step S6.5 may differ depending on the host material and defects of the system. For example, different pulse wavelengths may be used in the laser writing step. The relatively small bandgap of silicon (compared to diamond) requires the use of a longer wavelength for laser writing.

### Method for Operation

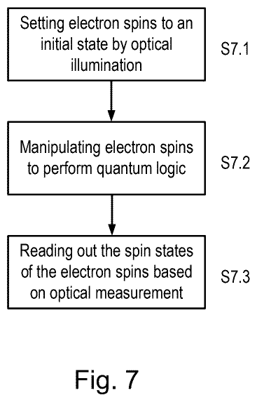

Referring to FIG. 7, a first method of operating the first system 1 is shown.

First, the electron spins corresponding to the nitrogen-vacancy centres 5_{i,k}, 5_{i+1,k}, 5_{i,k+1} . . . 5_{n,m} are set to an initial state using optical illumination. This may be assisted by applying a magnetic field from a magnet (step S7.1). Next, the electron spins are manipulated using magnetic pulses to perform quantum logic (step S7.2). The magnetic pulses may be microwave pulses that cause magnetic resonance of the electron spins corresponding to nitrogen-vacancy centres. Alternatively, the magnetic pulses may be RF pulses that cause magnetic resonance of the nuclear spin(s) corresponding to additional atomic nuclei having non-zero nuclear spin. By applying electric and/or magnetic fields to the electron spins and/or the nuclear spin(s), qubits may be created. Then, the spin states of the nitrogen-vacancy centres are read out by measurement based on at least one optical transition (step S7.3).

The first method may also include transferring quantum information by hyperfine coupling between the nuclear spin of the additional atomic nucleus and the electron spin of the nitrogen-vacancy centre that the additional atomic nucleus is disposed within 2 nm of, and/or transferring quantum information between electron spins corresponding to nitrogen-vacancy centres.

The first method may also include creating entanglement between the electron spins of the nitrogen-vacancy centres using a projective readout method.

The method may also include cooling the first system 1 to less than 10 K. For example, the method may include cooling the first system 1 to between 3 K and 7 K. For example, the method may include cooling the first system 1 to 4 K. Performing the method at, for example, 5 K can help improve the entanglement rate. Performing method at cryogenic temperatures may also help to improve the spin coherence times of nuclear and electron spin states.

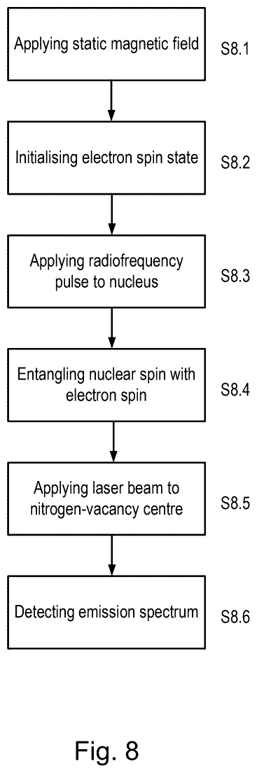

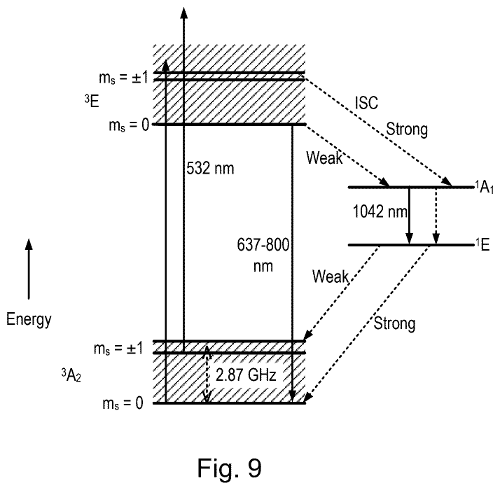

Referring also to FIG. 8, a second method for operating the first system 1 hereinbefore described is shown. The second method is an example of the first method, and involves providing the spin state of one or more nuclei as a qubit(s). Referring also to FIG. 9, the energy level structure of a nitrogen-vacancy centre consists of a triplet ground state, ³A₂, a triplet excited state, ³E, and two singlet states: ¹A₁ and ¹E. Application of a magnetic field makes to the degenerate mₛ=±1 levels non-degenerate in the triplet ground state (known as “Zeeman splitting”).

As a first step, a magnetic field is applied to the diamond membrane 2 (step S8.1). The magnetic field may be static, and may be applied using the magnet 17 hereinbefore described to give rise to Zeeman splitting.

Next, each nitrogen-vacancy centre is initialised by applying laser light to the diamond membrane 2 (step S8.2). The laser light may be from a light source 14, and may be a constant laser light or a pulsed laser light. The wavelength of the laser light may be between 500 nm and 700 nm. For example, the wavelength of the laser light may be resonant with the nitrogen-vacancy centres and have a wavelength of 637 nm. Alternatively, the wavelength of the laser light may be between 500 nm and 600 nm. For example, the wavelength of the laser light may be 532 nm.

The process of initialisation refers to the excitation of a nitrogen-vacancy centre from the triplet ground state to the triplet excitation state, followed by a relaxation back to the ground state. The initialisation mechanism and initialised state depend on the optical transition that is pumped. For example, under excitation at a wavelength of 532 nm, nitrogen-vacancy centres can be initialised into the mₛ=0 ground state.

As hereinbefore explained, the spin state of one or more nuclei can be provided as a qubit(s).

For a given nucleus, for example a ¹³C nucleus, a radiofrequency pulse is applied by a signal generator, for example the electrical oscillator 17 (step S8.3). The frequency of the pulse could be from 1 to 1000 kHz and the pulse duration could be from 5 to 5000 μs. Step S8.3 can performed when the apparatus 10 is in a “write mode”. The spin state of the nucleus is switched by the radiofrequency pulse due to nuclear magnetic resonance. During this step, more than one nucleus may be applied with radiofrequency pulses. In one example, the spin state of at least 100,000 nuclei in the diamond article 1 is switched during this step.

The energy levels of the nitrogen-vacancy centre are further split by the nuclear spin state of the nucleus due to the hyperfine interaction. In this way, the electron spin state can be used to read the nuclear spin state.

For each nucleus being used to provide a qubit, the spin state of the nucleus is entangled with the electron spin state of the nitrogen-vacancy centre (step S8.4). This makes use of the hyperfine coupling between the electron spin and the nuclear spin, as well as microwave or radiofrequency pulses to excite magnetic resonance of the electron or nuclear spin respectively. A combination of pulses to excite both the electron and the nuclear spin can be used. Selective pulses can be used that excite the nuclear spin conditionally on the state of the electron spin, and that excite the electron spin conditionally on the state of the nuclear spin. The two spins can be entangled by selectively flipping one of them conditionally on the state of the other one, when the latter is in a superposition state, ideally an equal superposition state.

The method of generating entanglement between a nitrogen-vacancy centre electron spin and any nearby nuclear spins is different to that of optically-mediated entanglement between two nitrogen-vacancy centres described earlier. It is deterministic rather than probabilistic and does not require measurement of the qubit to herald the outcome.

Typically, the entanglement between the nitrogen-vacancy centre and the several nuclei is created using at least one antenna to deliver microwave or RF electromagnetic fields. Several nuclear spin states may be entangled with a single nitrogen-vacancy centre.

After entanglement, nuclear spin states can be measured by first transferring the state onto the electron spin of the nearby nitrogen-vacancy centre and then using optically-detected magnetic resonance to measure the electron spin state. Optically detected magnetic resonance is typically done by applying a laser beam to the diamond article using the light source 14 (step S8.5). The nitrogen-vacancy centres are optically excited by a beam with wavelength of, for example, between 500 nm and 600 nm, or at the resonant wavelength of 637 nm. Relaxation of the nitrogen-vacancy centres produces fluorescence, and this fluorescence is detected (step S8.6), for example using a detector 15. The fluorescence of each nitrogen-vacancy centre forms an emission spectrum (not shown) comprising spectral lines.

The intensity of the fluorescence from a given nitrogen-vacancy centre indicates the state of its electron spin.

Steps S8.5 and S8.6 are performed when the apparatus 7 is in a “read mode”.

When performing the method, the apparatus 7 initialises, controls, entangles and reads out the state of a large number of electron and nuclear spins (for example, at least 100,000). Just the electron spins or just the nuclear spins could be used to store the quantum information. The former can be controlled faster but have shorter coherence times.

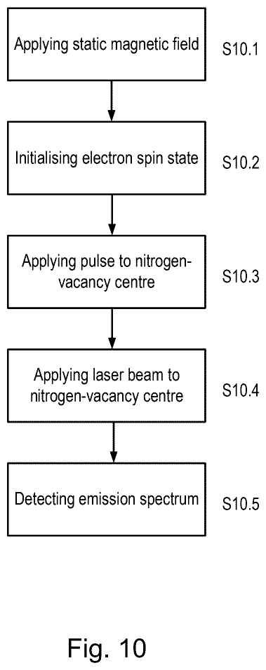

Referring also to FIG. 10, a third method of operating the apparatus 10 is shown. The third method is an example of the first method. The third method involves providing the electron spin state of the nitrogen-vacancy centres as qubit.

Steps S10.1 and S10.2 are the same as steps S8.1 and S8.2 hereinbefore described with respect to the second method.

After initialisation, the electron spin state of at least one nitrogen-vacancy centre is modified by applying a microwave pulse from the light source 14 (step S10.3). The microwave pulse may be produced by using control circuitry 16 to drive a current through a wire (not shown) on the first system 1.

The electron spin state is switched by triggering a transmission from the mₛ=0 ground state to either the mₛ=±1 or mₛ=−1 level in the ³A₂ state. This occurs during a “write mode” of the apparatus 10.

The electron spin state of one or more nitrogen-vacancy centres can be read out during a “read mode” of the apparatus. The electron spin states are read out in a similar way as hereinbefore described in steps S2.4 and S2.5 of the first method.

Specifically, a laser beam is applied to the first system 1 (step S10.4) so as to produce fluorescence. This fluorescence is then detected (step S10.5). For example, the fluorescence may be captured by a detector 12 in the form of emission spectra or an intensity, or by counting the number of photons collected. The intensity or the number of photons collected indicates the electron spin state of the nitrogen-vacancy centre.

The second system (not shown) may be operated in a similar way to the first system 1. Other systems (not shown) having a host material and/or defects different to the first system 1 or second system may be operated in a similar way to the first system 1.

The specific parameters for the steps of initialisation (S7.1), spin control (S7.2), and read out (S7.3), for example, may vary for the second and other systems. For example, the parameters may depend on the energy level structure of specific vacancy centres.

### Modifications

It will be appreciated that various modifications may be made to the embodiments hereinbefore described. Such modifications may involve equivalent and other features which are already known in the design and use of quantum information processing systems, and which may be used instead of or in addition to features already described herein. Features of one embodiment may be replaced or supplemented by features of another embodiment.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A system for quantum information processing comprising:
a body of material having first and second opposite faces; and
at least one two-dimensional array of defects embedded in the body of material at a depth of between 0.2 μm and 6 μm from the first face.

2. The system of claim 1, wherein the material is an insulator, semiconductor, or semiconductor alloy.

3. The system of claim 1, wherein a spin state of an electron corresponding to a defect is programmable to store quantum information.

4. The system of claim 1, wherein the defects are vacancy centres.

5. The system of claim 4, wherein the material is a single-crystal diamond membrane.

6. The system of claim 5, wherein the vacancy centres are negatively charged silicon vacancy centres, germanium vacancy centres, tin vacancy centres, or lead vacancy centres.

7. The system of claim 1, wherein the body of material is single-crystal silicon, single-crystal silicon carbide, zinc oxide, gallium nitride, amorphous silicon dioxide, or rare-earth-doped laser crystals.

8. The system of claim 7, wherein the rare-earth-doped laser crystals are Y₂SiO₅ doped with ions of europium, neodymium, and/or erbium.

9. The system of claim 7, wherein the body of material is silicon carbide, the vacancy centres are silicon vacancy centres or complex vacancy centres.

10. The system of claim 4, wherein the body of material is a single-crystal diamond membrane and the vacancy centres are nitrogen-vacancy centres.

11. The system of claim 10, further comprising:
an additional atomic nucleus having a non-zero nuclear spin disposed within 2 nm of a nitrogen-vacancy centre in the array, the nitrogen-vacancy centre having a corresponding electron spin, such that quantum information is transferred between the nuclear spin and the electron spin by hyperfine coupling.

12. The system of claim 10, wherein the at least one two-dimensional array of nitrogen-vacancy centres comprises between 10 and 10 million nitrogen-vacancy centres.

13. The system of claim 1, wherein the defects are donors.

14. The system of claim 13, wherein the material is silicon carbide and the donors are vanadium atoms.

15. The system of claim 1, wherein the material is silicon and the defects are involving carbon atoms provided in the silicon, for example G centre, T centre, I centre, M centre or W centre defects.

16. An apparatus comprising:
the system of claim 1;
first and second optical reflectors between which the system is interposed, the first and second optical reflectors configured to form microcavities tuned into resonance or near-resonance with at least one optical transition of the vacancy centres; and
at least one antenna configured to apply a magnetic field to control electron spin states corresponding to vacancy centres.

17. The apparatus of claim 16, wherein one or both of the optical reflectors is a distributed Bragg reflector or a diamond surface or a metallic layer or any other engineered reflector.

18. The apparatus of claim 16, further comprising:
a tuning layer between the optical reflectors.

19. The apparatus of claim 18, wherein:
the tuning layer is a layer of a material that displays a linear electro-optic effect, such that a refractive index can be modified by application of an electric field; and/or
the tuning layer is a layer of a material that changes in thickness in response to an applied stimulus, for example, application of an electric field, optical or electron beam irradiation, or a current or a physical force; and/or
the tuning layer is layer of a phase-change material having a refractive index that is modifiable by laser processing or thermal treatment.

20. A method of fabricating the system for quantum information processing of claim 1, the method comprising, wherein the defects are vacancy centres:
creating vacancies in a sample of material having an initial surface by laser processing, electron irradiation, ion implantation, atom implantation, or neutron irradiation;
forming vacancy centres in the sample of material by thermal annealing or laser-induced vacancy diffusion; and
etching the initial surface of the sample of material to fabricate the system.

21. The method of claim 20, further comprising:
creating vacancies by laser processing, wherein the laser processing comprises applying laser pulses to a plurality of sites to form at least one two-dimensional array of vacancy centres embedded in the sample of material.

22. A method of operating the system for quantum information processing of claim 1 comprising, wherein the defects are vacancy centres:
setting electron spins corresponding to the vacancy centres to an initial state using optical illumination;
manipulating the electron spins using magnetic pulses to perform quantum logic; and
reading out the spin states of the vacancy centres based on measurement of at least one optical transition.

23. The method of claim 22, further comprising:
creating entanglement between electron spins of the vacancy centres using a projective readout method.

24. The method of claim 22, wherein the method is a method of operating a system for quantum information processing comprising:
a body of material having first and second opposite faces; and
at least one two-dimensional array of defects embedded in the body of material at a depth of between 0.2 μm and 6 μm from the first face,
an additional atomic nucleus having a non-zero nuclear spin disposed within 2 nm of a nitrogen-vacancy centre in the array, the nitrogen-vacancy centre having a corresponding electron spin, such that quantum information is transferred between the nuclear spin and the electron spin by hyperfine coupling,
wherein:
the body of material is a single-crystal diamond membrane and the vacancy centres are nitrogen-vacancy centres, and
the method further comprises:
transferring quantum information by hyperfine coupling between the nuclear spin of the additional atomic nucleus and the electron spin of the nitrogen-vacancy centre that the additional atomic nucleus is disposed within 2 nm of.

25. The method of claim 22, further comprising:
cooling the system to less than 30 K.
